(19) United States
(12) Patent Application Publication
(10) Pub. No.: US 2022/0102438 A1
(43) Pub. Date: Mar. 31, 2022

(54) DISPLAY PANEL AND DISPLAY DEVICE

(71) Applicant: WUHAN TIANMA MICROELECTRONICS CO., LTD., Wuhan (CN)

(72) Inventors: Lu XIAO, Wuhan (CN); Yangzhao MA, Wuhan (CN); Minhong KIM, Wuhan (CN); Zhiqiang XIA, Wuhan (CN)

(73) Assignee: WUHAN TIANMA MICROELECTRONICS CO., LTD., Wuhan (CN)

(21) Appl. No.: 17/548,601

(22) Filed: Dec. 13, 2021

(30) Foreign Application Priority Data
Jul. 1, 2021 (CN) 202110746237.4

(51) Int. Cl. H01L 27/32; H01L 51/52

(52) U.S. Cl. CPC H01L 27/3216; H01L 51/5284; H01L 27/3218

(57) ABSTRACT

Disclosed are a display panel and a display device. The display panel includes pixel repetitive units arranged in an array. Each pixel repetitive unit includes two first sub-pixels, two second sub-pixels and four third sub-pixels. In the display panel, a first sub-pixel is located among the four third sub-pixels, a second sub-pixel is located among the four third sub-pixels, and a third sub-pixel is simultaneously located between the two first sub-pixels and between the two second sub-pixels. Centers of the four third sub-pixels surrounding the first sub-pixel constitute a first irregular quadrangle, where lengths of each pair of opposite edges of the first irregular quadrangle 21 are not equal. Embodiments of the present disclosure may improve the display effect of the display panel.

### CROSS-REFERENCE TO RELATED APPLICATION(S)

This application claims priority to Chinese Patent Application No. 202110746237.4 filed Jul. 1, 2021, the disclosure of which is incorporated herein by reference in its entirety.

### FIELD

Embodiments of the present disclosure relate to the field of display technologies and, in particular, to a display panel and a display device.

### BACKGROUND

With the wide application of the organic light emitting diode (OLED) display panels, users have an increasingly higher demand for the display effect of display panels.

In related art, the arrangement such as an RGBG arrangement, a YYG arrangement and the like is commonly used in OLED pixel arrangement. But in a case where the RGBG arrangement is used, text is blurred, strokes are thick and picture display is blurred, while in a case where the YYG arrangement is used, serrations of displayed text font are apparent, in both cases of which, the display effect is not satisfactory.

In view of this, how to improve the display effect of a display panel has become an urgent problem.

### SUMMARY

Embodiments of the present disclosure provide a display panel and a display device to improve the display effect of the display panel.

In some embodiments of the present disclosure provide a display panel. The display panel includes pixel repetitive units arranged in an array.

Each pixel repetitive unit of the pixel repetitive units includes two first sub-pixels, two second sub-pixels and four third sub-pixels.

In the display panel, a first sub-pixel of the two first sub-pixels is located among the four third sub-pixels, a second sub-pixel of the two second sub-pixels is located among the four third sub-pixels, and a third sub-pixel of the four third sub-pixels is simultaneously located between the two first sub-pixels and between the two second sub-pixels. Centers of the four third sub-pixels surrounding the first sub-pixel constitute a first irregular quadrangle, where lengths of each pair of opposite edges of the first irregular quadrangle are not equal.

Embodiments of the present disclosure further provide a display device including the display panel provided in the embodiments: pixel repetitive units arranged in an array; each pixel repetitive unit includes two first sub-pixels, two second sub-pixels and four third sub-pixels; in the display panel, a first sub-pixel of the two first sub-pixels is located among the four third sub-pixels, a second sub-pixel of the two second sub-pixels is located among the four third sub-pixels, and a third sub-pixel of the four third sub-pixels is simultaneously located between the two first sub-pixels and between the two second sub-pixels; and centers of the four third sub-pixels surrounding the first sub-pixel constitute a first irregular quadrangle, where lengths of each pair of opposite edges of the first irregular quadrangle are not equal.

### BRIEF DESCRIPTION OF DRAWINGS

FIG. 1 is a structural diagram of a display panel according to an embodiment of the present disclosure;

FIG. 2 is a structural diagram of a pixel repetitive unit in the display panel shown in FIG. 1;

FIG. 3 is another structural diagram of a display panel according to an embodiment of the present disclosure;

FIG. 4 is another structural diagram of a display panel according to an embodiment of the present disclosure;

FIG. 5 is another structural diagram of a display panel according to an embodiment of the present disclosure;

FIG. 6 is another structural diagram of a display panel according to an embodiment of the present disclosure;

FIG. 7 is another structural diagram of a display panel according to an embodiment of the present disclosure;

FIG. 8 is another structural diagram of a display panel according to an embodiment of the present disclosure;

FIG. 9 is another structural diagram of a display panel according to an embodiment of the present disclosure;

FIG. 10 is another structural diagram of a display panel according to an embodiment of the present disclosure;

FIG. 11 is a partial structural diagram of a display panel according to an embodiment of the present disclosure;

FIG. 12 is a sectional view of the display panel shown in FIG. 11;

FIG. 13 is a partial structural diagram of a display panel in the related art;

FIG. 14 is another partial structural diagram of a display panel according to an embodiment of the present disclosure;

FIG. 15 is a sectional view of the display panel shown in FIG. 14;

FIG. 16 is another partial structural diagram of a display panel in the related art; and

FIG. 17 is a structural diagram of a display device according to an embodiment of the present disclosure.

### DETAILED DESCRIPTION

The present disclosure is further described in detail in conjunction with the drawings and the embodiments. It is to be understood that the embodiments set forth below are intended to illustrate and not to limit the present disclosure. Additionally, it is to be noted that for ease of description, merely part, not all, of structures related to the present disclosure are illustrated in the drawings. Moreover, the terms “first”, “second” and “third” in the embodiments of the present disclosure are merely used for descriptive purposes and have no essential meanings.

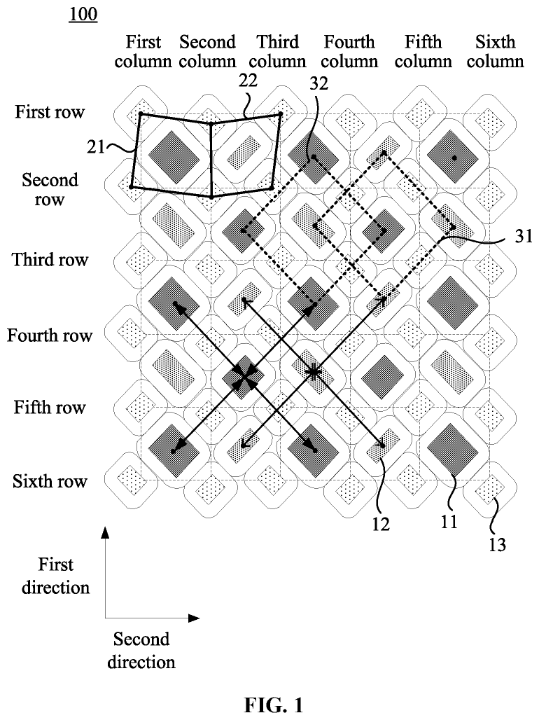

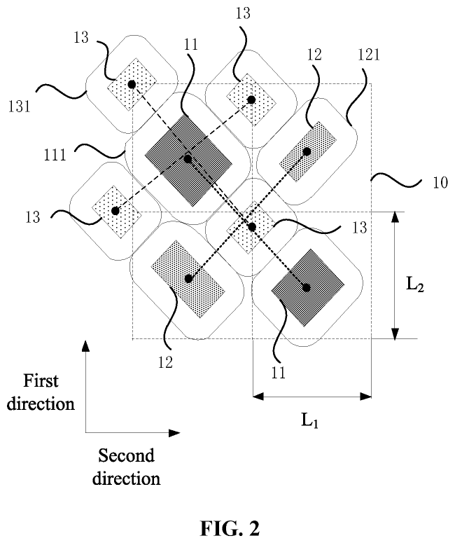

FIG. 1 is a structural diagram of a display panel according to an embodiment of the present disclosure, and FIG. 2 is a structural diagram of a pixel repetitive unit in the display panel shown in FIG. 1. Referring to FIGS. 1 and 2, a display panel 100 includes pixel repetitive units arranged in an array. Each pixel repetitive unit includes two first sub-pixels 11, two second sub-pixels 12 and four third sub-pixels 13. In the display panel, a first sub-pixel 11 is located among four third sub-pixels 13, a second sub-pixel 12 is located among four third sub-pixels 13, and a third sub-pixel 13 is simultaneously located between two first sub-pixels 11 and between two second sub-pixels 12. Centers of four third sub-pixels 13 surrounding the first sub-pixel 11 constitute a first irregular quadrangle 21, where lengths of each pair of opposite edges of the first irregular quadrangle 21 are not equal.

As shown in FIG. 2, in one pixel repetitive unit, a first sub-pixel 11 (such as the first sub-pixel 11 located at a top left corner) located among four third sub-pixels 13, a third sub-pixel 13 (such as the third sub-pixel 13 located at a lower right corner) is simultaneously located between two first sub-pixels 11 and between two second sub-pixels 12, and the pixel repetitive units is arranged along a first direction and a second direction in FIG. 1 to form the display panel shown in FIG. 1.

As shown in FIG. 1, in the display panel, each first sub-pixel 11 is located among four third sub-pixels 13, each second sub-pixel 12 is located among four third sub-pixels 13, and a third sub-pixel not at margin is simultaneously located between two first sub-pixels 11 and between two second sub-pixels 12. As can be seen form FIG. 1, compared with the existing arrangement modes such as the RGBG arrangement or the YYG arrangement, the pixel arrangement in the display panel provided in the embodiments of the present disclosure can make the distribution of first sub-pixels 11, second sub-pixels 12 and third sub-pixels 13 in the display panel more uniform, to improve the display effect of the display panel.

The first sub-pixel 11, the second sub-pixel 12 and the third sub-pixel 13 respectively emit light in different colors. In an embodiment, the first sub-pixel 11, the second sub-pixel 12 and the third sub-pixel 13 are respectively one of a red sub-pixel, a blue sub-pixel and a green sub-pixel and are different from each other.

As an example, the first sub-pixels 11 may be blue sub-pixels, the second sub-pixels 12 may be red sub-pixels and the third sub-pixels 13 may be green sub-pixels, or the first sub-pixels 11 may be red sub-pixels, the second sub-pixels 12 may be blue sub-pixels and the third sub-pixels 13 may be green sub-pixels. Thus, a pixel setting region 10 may include one blue sub-pixel (or one red sub-pixel) and one green sub-pixel, to achieve a color display by a pixel rendering method and improving image resolution (i.e., pixels per inch, short as PPI).

The pixel setting region 10 is region shaped in a rectangular defined by dashed lines extending along the first direction and the second direction in FIGS. 1 and 2. As shown in FIG. 1, the pixel setting region 10 covers an entire region of a first sub-pixel 11 and a partial region of four third sub-pixels 13 (a sum area of the partial region of four third sub-pixels 13 is equal to an area of a third sub-pixel 13) surrounding the first sub-pixel 11, or covers an entire region of a second sub-pixel 12 and a partial region of four third sub-pixels 13 (a sum area of the partial region of four third sub-pixels 13 is equal to an area of a third sub-pixel 13) surrounding the second sub-pixel 12, and the pixel setting region 10 includes a first sub-pixel 11 (such as a blue sub-pixel) and a third sub-pixel 13 (such as a green sub-pixel), or includes a second sub-pixel 12 (such as one red sub-pixel) and a third sub-pixel 13 (such as a green sub-pixel).

It should be noted that, FIG. 1 and FIG. 2 merely illustrate the first sub-pixels 11, the second sub-pixels 12 and the third sub-pixels 13 in a rectangular shape, but it is not to limit the shape of the first sub-pixel 11, the shape of the second sub-pixel 12 and the shape of the third sub-pixel 13 in the embodiments of the present disclosure. A boundary of the rectangle represents an opening boundary of a corresponding sub-pixel. Taking the display panel as an OLED display panel as an example, the boundary of the rectangle is an effective opening boundary of a sub-pixel in a pixel definition layer (PDL), which represents a light-emitting area (opening area) of the sub-pixel.

It should also be noted that the pixel repetitive unit shown in FIG. 2 is merely an example and is not limited thereto. For example, four third sub-pixels 13 in the pixel repetitive unit may be disposed around a same second sub-pixel 12, and a third sub-pixel 13 is simultaneously located between two first sub-pixels 11 and between two second sub-pixels 12.

Further, as can be seen from FIG. 1, centers of four third sub-pixels 13 surrounding a first sub-pixel 11 constitute a first irregular quadrangle 21 with each pair of edges having unequal lengths In the embodiments of the present disclosure, and the design space of the display region can be fully utilized to make the pixel arrangement more compact. A center of a (third) sub-pixel refers to a geometric center of a light-emitting region of the sub-pixel, which can be determined according to the shape of the sub-pixel. Herein, merely the example in which the sub-pixel is rectangular in shape is illustrated.

In addition, compared to an arrangement (e.g. a diamond arrangement) in which a rectangle is constituted by the centers of the four third sub-pixels (e.g. green sub-pixels) surrounding the first sub-pixel (e.g. a red sub-pixel or a blue sub-pixel), in this embodiment, since the centers of four third sub-pixels 13 surrounding the first sub-pixel 11 constitute an irregular quadrangle, it is possible to set an unchanged number of third sub-pixels 13 in the display region by reducing the light-emitting areas of part or all of the third sub-pixels 13 in a case where the display area is not changed, to ensure that the pixel resolution PPI is unchanged. In a case where a light-emitting area of a third sub-pixel 13 is reduced, correspondingly, on the one hand, an opening area of a mask corresponding to the third sub-pixel 13 can be reduced, and the intensity of the mask can be enhanced and the yield of the evaporation process can be improved; on the other hand, for the OLED display panel in which a sub-pixel includes a light-emitting element, it is easy to understand that, in a case where a light-emitting layer area of the light-emitting element (OLED) is reduced, an area of an anode of the light-emitting element can be reduced. Therefore, for techniques such as fingerprint-on-display (FOD), since a light sensing sensor is disposed under the display region, in a case where the area of the anode of the light-emitting element is reduced, more space can be vacated to achieve light transmission, to improve the light transmittance of an FOD region and improving the fingerprint identification effect.

In the display panel provided in the embodiments of the present disclosure, the two first sub-pixels, the two second sub-pixels and the four third sub-pixels constitute one pixel repetitive unit, and the pixel repetitive units are arranged in an array in the display panel. One first sub-pixel is located among the four third sub-pixels, one second sub-pixel is located among the four third sub-pixels, and one third sub-pixel is simultaneously located between the two first sub-pixels and between the two second sub-pixels, and, compared with the existing arrangement modes such as the RGBG arrangement or the YYG arrangement, the distribution of first sub-pixels, second sub-pixels and third sub-pixels in the display panel is more uniform, and the display effect of the display panel is improved. In addition, the centers of four third sub-pixels surrounding the first sub-pixel to form the first irregular quadrangle with each pair of opposite edges having unequal lengths, and the design space of a display region can be fully utilized to make the pixel arrangement more compact. Furthermore, based on the design of the irregular quadrangle, the pixel resolution can be guaranteed by reducing the light-emitting area of the third sub-pixel, correspondingly, the opening area of the mask can be reduced to improve the intensity of the mask, the area of the anode of the light-emitting element can also be reduced, the light transmittance of the FOD region can be improved, and the fingerprint identification effect can be improved.

With further reference to FIGS. 1 and 2, a fringe-frame around each first sub-pixel 11 represents virtual edges 111 of each first sub-pixel 11, a fringe-frame around each second sub-pixel 12 represents virtual edges 121 of each second sub-pixel 12, and a fringe-frame around each third sub-pixel 13 represents virtual edges 131 of each third sub-pixel 13. The virtual edges refer to an outer boundary of a sub-pixel in case of being shielded by a mask and does not really exist. In an embodiment, a pixel opening of the first sub-pixel 11, a pixel opening of the second sub-pixel 12 and a pixel opening of the third sub-pixel 13 can be prepared in different processes using different masks respectively to avoid mutual influence and reduce preparation difficulty. In addition, in an embodiment, virtual edges 131 of each third sub-pixel 13 are in contact with virtual edges 111 of two adjacent first sub-pixels 11, and virtual edges 131 of each third sub-pixel 13 is in contact with virtual edges 121 of two adjacent second sub-pixels 12. In this way, the arrangement of the first sub-pixels 11, the second sub-pixels 12 and the third sub-pixels 13 can be made more compact without obvious hollow regions, which can effectively avoid obvious gaps, space waste, and possible mura.

With further reference to FIG. 1, in an embodiment, centers of four third sub-pixels 13 surrounding the second sub-pixel 12 constitute a first irregular quadrangle 22, where lengths of each pair of opposite edges of the first irregular quadrangle 22 are not equal. By arranging the centers of four third sub-pixels 13 surrounding the second sub-pixel 12 to constitute the first irregular quadrangle 22, the design space of the display region can be fully utilized to make the pixel arrangement more compact. Furthermore, based on the design of the irregular quadrangle, the pixel resolution can be guaranteed by reducing the light-emitting areas of the third sub-pixels, correspondingly, the opening area of the mask can be reduced to improve the intensity of the mask, also the area of the anode of the light-emitting element can be reduced, and the light transmittance of the FOD region can be improved, and the fingerprint identification effect can be improved. Principles thereof have been described above and would not be repeated herein.

With further reference to FIG. 1, in an embodiment, light emitting areas of four third sub-pixels 13 are equal.

As shown in FIG. 1, four third sub-pixels 13 surround one first sub-pixel 11, or four third sub-pixels 13 surround one second sub-pixel 12, and in a case where setting regions for third sub-pixels 13 are determined, setting regions for first sub-pixels 11 and setting regions for second sub-pixels 12 can be determined. The light-emitting areas of the third sub-pixels 13 are equal in the embodiments of the present disclosure, which can reduce the design difficulty and the preparation process difficulty.

In this embodiment, in a case where the centers of four third sub-pixels 13 surrounding the first sub-pixel 11 constitute the first irregular quadrangle 21, the centers of four third sub-pixels 13 surrounding the second sub-pixel 12 constitute the second irregular quadrangle 22, and the light-emitting areas of four third sub-pixels 13 are equal, light-emitting areas of two first sub-pixels 11 in each pixel repetitive unit may be not equal, and/or light-emitting areas of two second sub-pixels 12 in each pixel repetitive unit may be not equal. As shown in FIGS. 1 and 2, both the light-emitting areas of two first sub-pixels 11 and the light-emitting areas of two second sub-pixels 12 in each pixel repetitive unit are not equal. In this way, the display panel may have first sub-pixels 11 with two different light emitting areas and/or second sub-pixels 12 with two different light emitting areas, to satisfy different design requirements.

For example, in a practical application scenario, with the increase of the PPI, the opening area (light-emitting area) of a sub-pixel is relative small, so it is necessary to increase a driving current to satisfy the brightness requirements of the display. However, in a case where the OLED operates under large driving current, it is easy to cause device aging and shorten the service life of display devices. In the embodiments of the present disclosure, the sub-pixels (that is, the first sub-pixels 11 and/or the second sub-pixels 12) with different opening areas are formed through pixel arrangement, and the sub-pixels with a relative small opening area can be driven based on the driving current corresponding to the sub-pixels with a relative large opening area. Since the driving current corresponding to the sub-pixels with the relative large opening area is relative small under a same brightness, the phenomenon of device aging caused by the large driving current can be avoided, and the service life of the display device can be prolonged.

For example, in another practical application scenario, in order to achieve full screen, technologies of camera under panel emerged as the times required. In order to achieve camera under panel, the display region corresponding to a position where a camera is located needs to be transparent. In the embodiments of the present disclosure, the sub-pixels (that is, the first sub-pixels 11 and/or the second sub-pixels 12) with different opening areas are formed through the pixel arrangement, and the sub-pixels with a relative large opening area can be removed from the camera under panel placement region to achieve light transmission and improve light transmittance, at the same time, the sub-pixels with a relative small opening area can be retained to ensure that the camera under panel placement region can achieve display, to achieve full-screen display.

With further reference to FIG. 1, in an embodiment, a distance between a first sub-pixel 11 and four most adjacent first sub-pixels 11 is equal.

A distance between two first sub-pixels 11 may refer to a distance between centers of these two first sub-pixels 11. As shown in FIG. 1, for a first sub-pixel 11 surrounded by four third sub-pixels 13 respectively located at 2nd column 4th row, 3rd column 4th row, 2nd column 5th row, and 3rd column 5th row, a distance between the first sub-pixel 11 and each of the four most adjacent third sub-pixels 13 is equal, and the arrangement of the first sub-pixels 11 can be more uniform.

With further reference to FIG. 1, in an embodiment, a distance between a second sub-pixel 12 and four most adjacent second sub-pixels 12 is equal.

A distance between two second sub-pixels 11 may refer to a distance between centers of these two second sub-pixels 12. As shown in FIG. 1, for a second sub-pixel 12 surrounded by four third sub-pixels 13 respectively located at 3rd column 4th row, 4th column 4th row, 3rd column 5th row, 4th column 5th row, a distance between the second sub-pixel 12 and each of the four most adjacent second sub-pixel 12 is equal, and the arrangement of the second sub-pixels 12 can be more uniform.

With further reference to FIG. 1, in an embodiment, centers of four second sub-pixels 12 most adjacent to a same first sub-pixel 11 constitute a first rectangle 31, a first diagonal of the first rectangle 31 is parallel to a first direction, a second diagonal of the first rectangle 31 is parallel to a second direction, and the first direction intersects the second direction (FIG. 1 is illustrated by taking the orthogonality of the first direction and the second direction as an example).

As shown in FIG. 1, for a first sub-pixel 11 surrounded by four third sub-pixels 13 located at 4th column 2nd row, 5th column 2nd row, 4th column 3rd row and 5th column 3rd row, respectively, centers of the four second sub-pixels 12 most adjacent to the first sub-pixel 11 constitute a first rectangle 31, two diagonals of the first rectangle 31 are parallel to the first direction and the second direction, respectively, and the arrangement of the second sub-pixels 12 can be more uniform. Further, a shape of a second sub-pixel 12 may be a rectangle, as shown in FIG. 1, two pairs of opposite edges of the second sub-pixel 12 may be respectively parallel to two pairs of opposite edges of the first rectangle 31, and a space enclosed by four third sub-pixels 13 is fully utilized to make the pixel arrangement more compact. In addition, in a case where a distance between a second sub-pixel 12 and four second sub-pixels 12 most adjacent thereto is equal, the first rectangle 31 is a square.

In an embodiment, centers of four first sub-pixels 11 most adjacent to a same second sub-pixel 12 constitute a second rectangle 32, a first diagonal of the second rectangle 32 is parallel to the first direction, a second diagonal of the second rectangle 32 is parallel to the second direction, and the first direction intersects the second direction.

As shown in FIG. 1, for one second sub-pixel 12 surrounded by four third sub-pixels 13 located at 3rd column 2nd row, 4th column 2nd row, 3rd column 3rd row and 4th column 3rd row, respectively, centers of four first sub-pixels 11 most adjacent to a second sub-pixel 12 constitute a second rectangle 32, two diagonals of the second rectangle 32 are parallel to the first direction and the second direction respectively, and the arrangement of the first sub-pixels 11 can be more uniform. Further, a shape of a first sub-pixel 11 may be a rectangle, as shown in FIG. 1, two pairs of opposite edges of the first sub-pixel 11 are parallel to two pairs of opposite edges of the second rectangle 32 respectively, and a space enclosed by four third sub-pixels 13 is fully utilized to make the pixel arrangement more compact. In addition, in a case where a distance between a first sub-pixel 11 and four most adjacent first sub-pixels 11 is equal, the second rectangle 32 is a square.

With further reference to FIG.1, in an embodiment, each first sub-pixel 11, each second sub-pixel 12 and each third sub-pixel 13 are respectively a rectangular in shape, and an aspect ratio L/W of the rectangle satisfies 1≤L/W≤1.5.

Considering that the larger the aspect ratio of the stretching and mask process, the easier the stretching is to deform and the greater the deformation degree is. Further, the etching accuracy in all directions is difficult to control during anisotropic etching, therefore, in an embodiment, the aspect ratio of each of the first sub-pixels 11, the second sub-pixel 12 and the third sub-pixel 13 may be in a range from 1 to 1.5, to ensure the production yield and reduce the process difficulty.

It should be noted that, the pixel arrangement shown in FIG.1 is merely an example rather than a limitation. As described above, after the setting regions for the third sub-pixels 13 are determined, the setting regions for first sub-pixels 11 and the setting regions for second sub-pixels 12 are determined accordingly. Hereinafter, the pixel arrangement in the display panel will be described in further detail based on different arrangement modes of the third sub-pixels 13. Arrangement features of each type of sub-pixels described in the above embodiments are applicable to any of the following pixel arrangement modes, and will not be described hereafter.

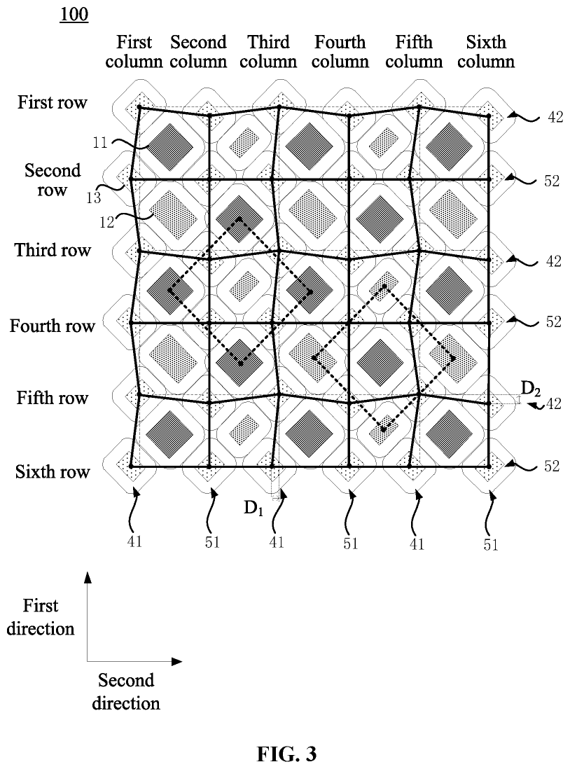

FIGS. 3 to 9 are structural diagrams of a display panel according to another embodiment of the present disclosure. Referring to FIG.1 and FIGS. 3 to 9, in an embodiment, among third sub-pixels 13 arranged along a first direction, centers of third sub-pixels 13 in an odd-th line are located in a first wavy line 41, and centers of third sub-pixels 13 in an even-th line are located in a first straight line 51; or centers of third sub-pixels 13 in an odd-th line are located in a first straight line 51, and centers of third sub-pixels 13 in an even-th line are located in a first wavy line 41; where the first direction is a row direction or a column direction.

FIGS. 1 to 9 are illustrated by taking the first direction as the column direction. In other embodiments, the first direction may also be the row direction, and similar examples would not be described herein.

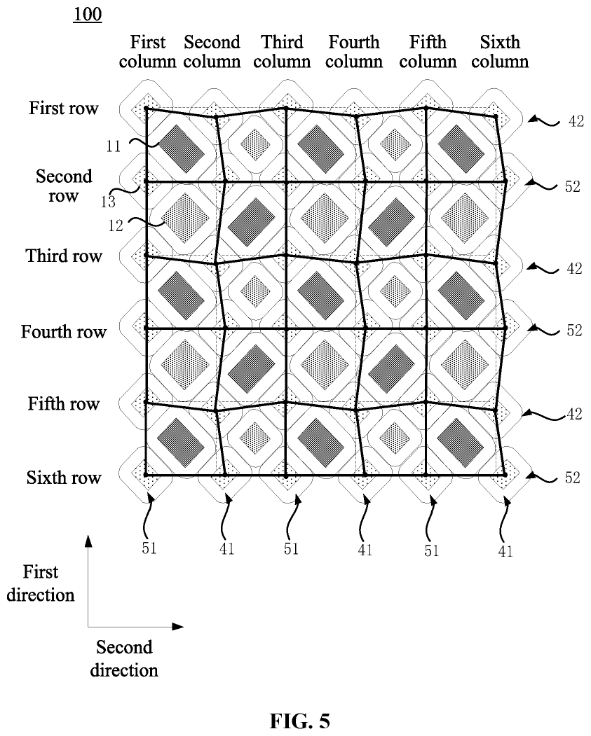

As an example, in the display panel shown in FIGS. 1, 3, 4 and 8, in the third sub-pixels 13 arranged along the first direction, the centers of the third sub-pixels 13 in an odd-th line are located in the first wavy line 41, and the centers of the third sub-pixels 13 in an even-th line are located in the first straight line 51. In the display panel shown in FIGS. 5, 6, 7 and 9, in the third sub-pixels 13 arranged along the first direction, the centers of the third sub-pixels 13 in an odd-th line are located in the first straight line 51, and the centers of the third sub-pixels 13 in an even-th line are located in the first wavy line 41.

In the embodiments of the present disclosure, in the third sub-pixels 13 arranged along the first direction, centers of third sub-pixels 13 in each row are alternately arranged in a straight line and a wavy line, and two opposite edges of the first irregular quadrangle 21 extending along the first direction are not parallel to each other, and lengths of the two opposite edges are not equal, as well as the lengths of the other two opposite edges are not equal, therefore, the lengths of each pair of opposite edges of the first irregular quadrangle 21 are not equal, and the lengths of each pair of opposite edges of the second irregular quadrangle 22 are not equal.

Referring to FIGS. 2 and 3, in an embodiment, a distance D1 is provided between a line connecting highest points in each of the first wavy lines 41 and a line connecting lowest points in the first wavy line 41, where 0<D1≤L1/8, and L1 is a length of a pixel setting region 10 along a second direction; and the second direction intersects the first direction. The pixel setting region 10 covers an entire region of a first sub-pixel 11 and a partial region of four third sub-pixels 13 surrounding the first sub-pixel 11, or the pixel setting region 10 covers an entire region of a second sub-pixel 12 and a partial region of four third sub-pixels 13 surrounding the second sub-pixel 12.

The meaning of the pixel setting region 10 is explained above, which would not be repeated herein. In the embodiments of the present disclosure, a distance between a line connecting highest points in each of the first wavy lines 41 and a line connecting lowest points in the first wavy line 41 is less than or equal to ⅛ of a length of a pixel disposed along the second direction. Not only can the centers of four third sub-pixels 13 surrounding the first sub-pixel 11 or the second sub-pixel 12 be formed into an irregular quadrangle with each pair of opposite edges having unequal lengths by a “wave” arrangement, but also the influence on the display effect caused by excessive fluctuation degree of the third sub-pixels arranged in a wave mode along the first direction can be avoided.

It should to be noted that in the drawings, the first direction and the second direction are orthogonal, the first direction is a column direction, and the second direction is a row direction.

Further, for third sub-pixels 13 arranged along the second direction, there may be different arrangement modes.

As a possible embodiment, referring to FIGS. 3 to 6, in an embodiment, in third sub-pixels 13 arranged along a second direction, centers of third sub-pixels 13 in an odd-th line are located in second wavy lines 42, and centers of third sub-pixels 13 in an even-th line are located in second straight lines 52; or centers of third sub-pixels 13 in an odd-th line are located in a second straight line 52, and centers of third sub-pixels 13 in an even-th line are located in a second wavy line 42; where the second direction intersects the first direction.

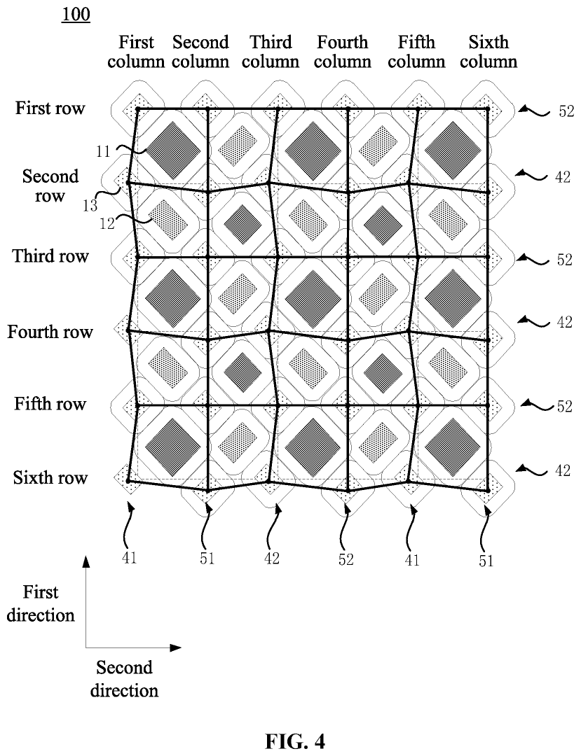

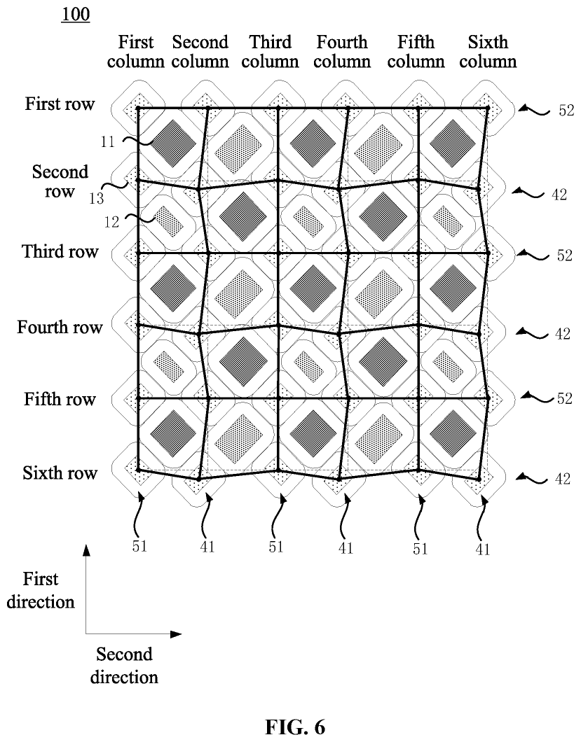

As an example, in FIGS. 3 and 5, in the third sub-pixels 13 arranged along the second direction, the centers of the third sub-pixels 13 in an odd-th line are located in the second wavy lines 42, and the centers of the third sub-pixels 13 in an even-th line are located in the second straight lines 52. In FIGS. 4 and 6, in the third sub-pixels 13 arranged along the second direction, the centers of the third sub-pixels 13 in an odd-th line are located in the second straight lines 52, and the centers of the third sub-pixels 13 in an even-th line are located in the second wavy lines 42.

In FIG. 3, third sub-pixels 13 in odd-th columns or odd-th rows are arranged in a wave mode, and third sub-pixels 13 in even-th columns or even-th rows are arranged in a straight line mode. In FIG. 4, third sub-pixels 13 in even-th rows or odd-th rows are arranged in a wave mode, and third sub-pixels 13 in odd-th rows or even-th columns are arranged in a straight line mode. In FIG. 5, third sub-pixels 13 in odd-th rows or even-th columns are arranged in a wave mode, and third sub-pixels 13 in even-th rows or odd-th rows are arranged in a straight line; and in FIG. 6, third sub-pixels 13 in even-th columns or even-th rows are arranged in a wave mode, and third sub-pixels 13 in odd-th columns or odd-th rows are arranged in a straight line mode.

As can be seen from FIGS. 3 to 6, a quadrangle constituted by the centers of four third sub-pixels 13 surrounding the first sub-pixel 11 is an irregular quadrangle with each pair of opposite edges having unequal lengths, and a quadrangle constituted by the centers of four third sub-pixels 13 surrounding the second sub-pixel 12 is an irregular quadrangle with each pair of opposite edges having unequal lengths. In this case, the light-emitting areas of two first sub-pixels 11 adjacent to a same third sub-pixel 13 may be not equal, or, light-emitting areas of two second sub-pixels 12 adjacent to a same third sub-pixel 13 may be not equal. For example, in FIGS. 3 and 5, the light-emitting areas of two second sub-pixels 12 adjacent to a same third sub-pixel 13 are different, and the light-emitting areas of two first sub-pixels 11 adjacent to a same third sub-pixel 13 are same; and in FIGS. 4 and 6, the light-emitting areas of two first sub-pixels 11 adjacent to a same third sub-pixel 13 are different, and the light-emitting areas of two second sub-pixels 12 adjacent to a same third sub-pixel 13 are same. In this way, the display panel may include first sub-pixels 11 with two different light-emitting areas or second sub-pixels 12 with two different light-emitting areas, to satisfy different design requirements. Details can be referred to the above explanation, which would not be repeated herein.

Referring to FIGS. 2 and 3, further in an embodiment, a distance D2 between a line connecting highest points in each of the second wavy lines 42 and a line connecting lowest points in each of the second wavy lines 42 satisfies 0<D2≤L2/8, and L2 is a length of a pixel setting region 10 along a second direction.

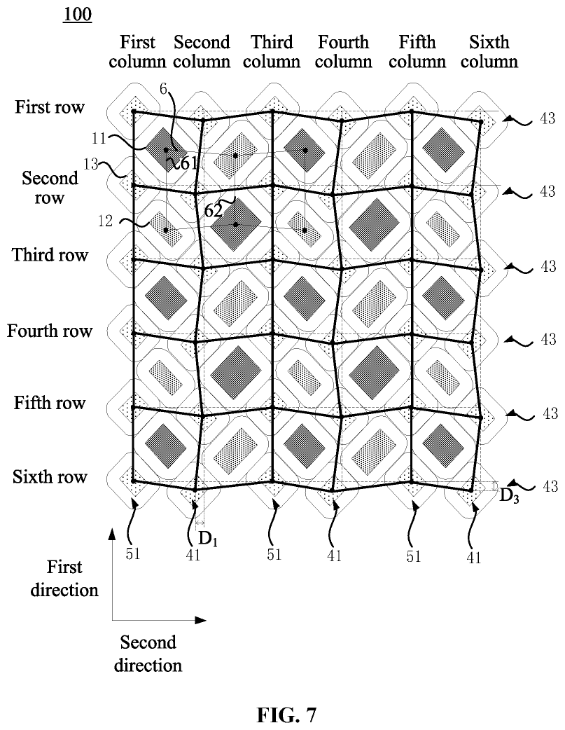

As another possible embodiment, reference to FIGS. 1 and 7, in an embodiment, centers of third sub-pixels 13 arranged along a second direction are located in third wavy lines 43, and the second direction intersects the first direction.

As shown in FIGS. 1 and 7, the centers of third sub-pixels 13 arranged along the second direction in each line are located in the third wavy lines 43, and the difference between the third wavy lines 43 is merely that the arrangement of the third sub-pixels 13 arranged in the first direction is different. In FIG. 1, third sub-pixels 13 in all rows are arranged in a wave mode, third sub-pixels 13 in odd-th columns are arranged in a wave mode, and third sub-pixels 13 in even-th columns are arranged in a straight line mode; and In FIG. 7, third sub-pixels 13 of all rows are arranged in a wave mode, third sub-pixels 13 in even-th columns are arranged in a wave mode, and third sub-pixels 13 in odd-th columns are arranged in a straight line mode. In the embodiments of the present disclosure, the third sub-pixels 13 arranged along the second direction are arranged in a wave mode, and the arrangement mode is simpler and the preparation difficulty can be reduced.

As can be seen from FIGS. 1 and 7, a quadrangle constituted by the centers of four third sub-pixels 13 surrounding the first sub-pixel 11 is an irregular quadrangle with each pair of opposite edges having unequal lengths, and a quadrangle constituted by the centers of four third sub-pixels 13 surrounding the second sub-pixel 12 is an irregular quadrangle with each pair of opposite edges having unequal lengths. In this case, the light-emitting areas of two first sub-pixels 11 adjacent to a same third sub-pixel 13 may be not equal, and light-emitting areas of two second sub-pixels 12 adjacent to a same third sub-pixel 13 may be not equal. In this case, the display panel may include first sub-pixels 11 with two different light-emitting areas and second sub-pixels 12 with two different light-emitting areas, to satisfy different design requirements. Details can be referred to the above explanation, which would not be repeated herein.

In an embodiment, in each third wavy line 43, a distance between a line connecting highest points of a third wavy line 43 and a line connecting lowest points of the third wavy line 43 is equal; and centers of four adjacent third sub-pixels 13 constitute an irregular trapezoid, and centers of two first sub-pixels 11 and centers of two second sub-pixels 12 adjacent to a same third sub-pixel 13 constitute an isosceles trapezoid 6.

Referring to FIG. 7, in a case where in each third wavy line 43, a distance between a line connecting highest points of a third wavy line 43 and a line connecting lowest points of the third wavy line 43 is equal, the third wavy lines 43 are parallel to each other, and centers of four adjacent third sub-pixels 43 surrounding the first sub-pixel 11 or the second sub-pixel 12 may constitute the irregular trapezoid, and the centers of two first sub-pixels 11 adjacent to a same third sub-pixel and the centers of two second sub-pixels 12 adjacent to a same third sub-pixel 13 constitute the isosceles trapezoid 6, therefore, the pixel arrangement is more uniform.

Referring to FIGS. 2 and 7, in an embodiment, a distance D3 between a line connecting highest points in each of the third wavy lines 43 and a line connecting lowest points in each of the third wavy lines 43 satisfies 0<D3<L2/8. Further, the isosceles trapezoid 6 includes a first edge 61 parallel to the first direction and a second edge 62 parallel to the first direction. A length a of the first edge 61 and a length b of the second edge 62 satisfy 0<|a-b|≤L2/4, and L2 is a length of a pixel setting region 10 along the first direction. The pixel setting region 10 covers an entire region of a first sub-pixel 11 and a partial region of four third sub-pixels 13 surrounding the first sub-pixel 11, or the pixel setting region 10 covers an entire region of a second sub-pixel 12 and a partial region of four third sub-pixels 13 surrounding the second sub-pixel 12.

The meaning of the pixel setting region 10 is explained above, which would not be repeated herein. The distance D3 between the line connecting highest points in each third wavy line 43 and the line connecting lowest points in each third wavy line 43 satisfies 0<D3≤L2/8, and the influence on the display effect caused by excessive fluctuation degree of the third sub-pixels 13 arranged in a wave mode along the second direction can be avoided. In view of 0<D3≤L2/8, it can be obtained that a length difference between the first edge 61 and the second edge 62 of the isosceles trapezoid 6 satisfies 0<|a-b|<L2/4.

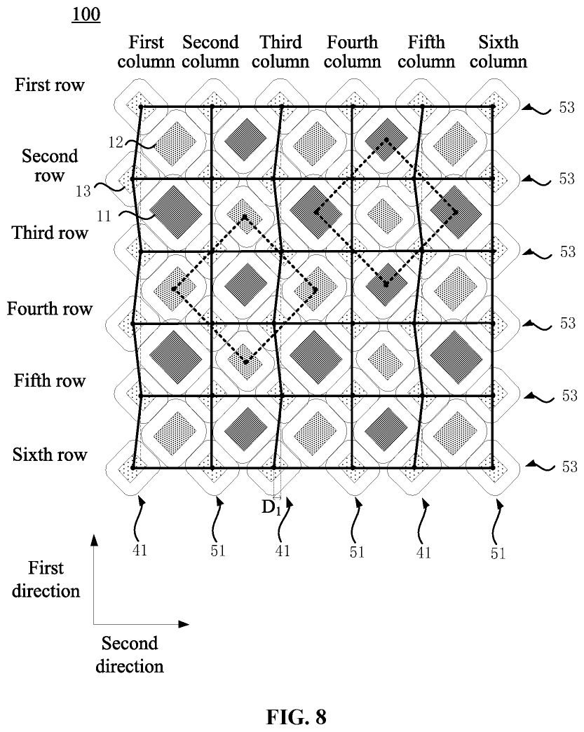

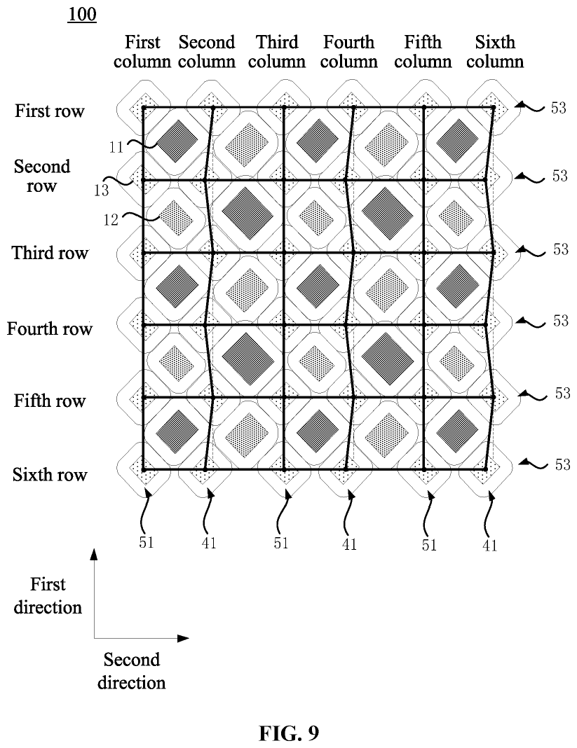

As another possible embodiment, reference to FIGS. 8 and 9, centers of third sub-pixels 13 arranged along a second direction are third straight lines 53, and the second direction intersects the first direction.

As shown in FIGS. 8 and 9, the centers of third sub-pixels 13 arranged along the second direction are located at the third straight lines 53, and the difference between the third wavy lines 43 is merely that the arrangement of the third sub-pixels 13 arranged in the first direction is different. In FIG. 8, third sub-pixels 13 in all rows are arranged in a straight line mode, third sub-pixels 13 in odd-th columns are arranged in a wave mode, and third sub-pixels 13 in even-th columns are arranged in a straight line mode; and in FIG. 9, third sub-pixels 13 in all rows are arranged in a straight line mode, third sub-pixels 13 in even-th columns are arranged in a wave mode, and third sub-pixels 13 in odd-th columns are arranged in a straight line mode. In the embodiments of the present disclosure, the third sub-pixels 13 arranged along the second direction are arranged in a straight line mode, and the arrangement mode is simpler and the preparation difficulty can be reduced.

As can be seen from FIGS. 8 and 9, a quadrangle constituted by the centers of four third sub-pixels 13 surrounding the first sub-pixel 11 is an irregular quadrangle with each pair of opposite edges having unequal lengths, and a quadrangle constituted by the centers of four third sub-pixels 13 surrounding the second sub-pixel 12 is an irregular quadrangle with each pair of opposite edges having unequal lengths. In this case, the light-emitting areas of two first sub-pixels 11 adjacent to a same third sub-pixel 13 may be not equal, and light-emitting areas of two second sub-pixels 12 adjacent to a same third sub-pixel 13 may be not equal. In this case, the display panel may include first sub-pixels 11 with two different light-emitting areas and second sub-pixels 12 with two different light-emitting areas, to satisfy different design requirements. Details can be referred to the above explanation, which would not be repeated herein.

The embodiments described above describes in detail the pixel arrangement in the display panel based on different arrangement modes of the third sub-pixels 13. The third sub-pixels 13 may be arranged in different arrangement modes, and the centers of four third sub-pixels 13 surrounding the first sub-pixel 11 constitute an irregular quadrangle with each pair of opposite edges having unequal lengths, and the centers of four third sub-pixels 13 surrounding the second sub-pixel 12 constitute an irregular quadrangle with each pair of opposite edges having unequal lengths, and then the display panel includes the first sub-pixels 11 with different light-emitting areas and/or the second sub-pixels 12 with different light-emitting areas, therefore, the design space can be fully utilized, the aperture ratio can be improved, the service life of the display device can be prolonged, the pixels can be uniformly arranged, there is no obvious hollow region, an obvious gap can be effectively avoided, the possible poor display such as mura can be avoided, and the display effect can be improved. Furthermore, based on the design in which the third sub-pixels 13 constitute an irregular quadrangle, the pixel resolution can be guaranteed by reducing the light-emitting areas of the third sub-pixels 13, and correspondingly, the opening areas of the masks can be reduced to improve the intensity of the mask, and the areas of the anodes of the light-emitting elements can be reduced to improve the light transmittance of the FOD region and improve the fingerprint identification effect.

In addition, referring to FIGS. 1 and 2 to 9, taking the first sub-pixel 11 as a blue sub-pixel, the second sub-pixel 12 as a red sub-pixel, and the third sub-pixel 13 as a green sub-pixel as an example, since human eyes are very sensitive to green, the third sub-pixels 13 are arranged in a wavy line mode described above, and the third sub-pixels 13 at the four margins are arranged in a form of wavy lines, merely part of third sub-pixels 13 are arranged close to margins of the display region, and the rest part of third sub-pixels 13 can be retracted to inside of the display region, therefore, the area proportion of the third sub-pixels 13 in the margin regions can be reduced and the green color effects at margins can be weakened. As an example, referring to FIG. 1, for an upper margin, the third sub-pixels 13 are arranged in the form of wavy lines, the third sub-pixels 13 in odd-th columns at the upper margin are closer to a margin, and the third sub-pixels 13 in even-th columns at the upper margin are retracted to the inside of the display region, and the area proportion of the third sub-pixels 13 in the margin regions is reduced, and the green color effect at margins is weakened. It can be understood that it is possible to ensure that the third sub-pixels 13 at the four margins are arranged in the form of wavy lines by adjusting the number of columns of the sub-pixels and the number of rows of the sub-pixels. The width of the margin region may be the width of one sub-pixel away from an edge of the margin region.

It should be noted that structures shown in FIGS. 1 and 2 to 9 merely take the third sub-pixels 13 located at four margins of the display region as an example, and the arrangement thereof is not limited.

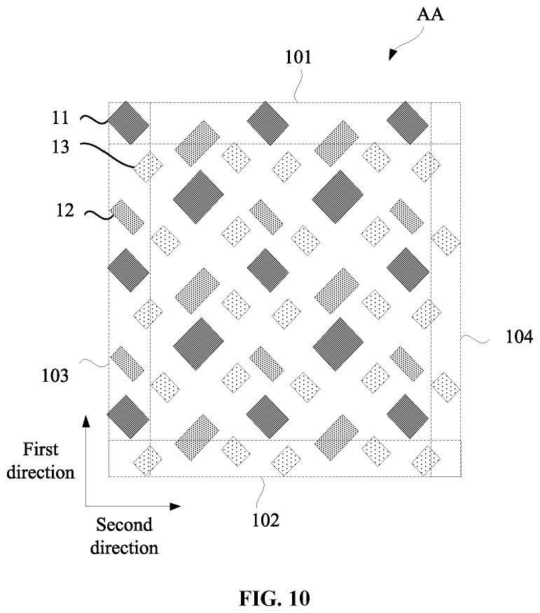

As an example, FIG. 10 is another structural diagram of a display panel according to an embodiment of the present disclosure. Referring to FIG. 10, in an embodiment, the display panel further includes a display region AA. The display region AA includes a first margin and a second margin opposite to each other along the first direction. The first margin includes a first pixel row 101, and the first pixel row 101 includes first sub-pixels 11 and at most part of second sub-pixels 12, but does not include a third sub-pixel 13.

As an example, the first sub-pixel 11 is a blue sub-pixel, the second sub-pixel 12 is a red sub-pixel, and the third sub-pixel 13 is a green sub-pixel. FIG. 10 illustrates the first direction as a column direction, the second direction as a row direction, the first margin as an upper margin, and the second margin as a lower margin.

In a case where an arrangement (e.g. a diamond arrangement) in which the centers of two first sub-pixels surrounding a third sub-pixel and the centers of two second sub-pixels surrounding the same third sub-pixel constitute a rectangle, and the centers of four third sub-pixels surrounding a second sub-pixel and/or a first sub-pixel constitute a rectangle, is adopted, a first sub-pixel (a blue sub-pixel) and a second sub-pixel (a red sub-pixel) close to the first margin are made to form a magenta color margin, and a third sub-pixel (a green sub-pixel) close to the second margin is made to form a green color margin.

As describe above, in the embodiments of the present disclosure, four third sub-pixels 13 surrounding a first sub-pixel 11 and/or a second sub-pixel 12 constitute an irregular quadrangle, and light-emitting areas of two first sub-pixels 11 adjacent to a same third sub-pixel 13 can be different, and/or light-emitting areas of two second sub-pixels 12 adjacent to a same third sub-pixel 13 can be different, and then center points of first sub-pixels 11 and center points of second sub-pixels 12, which are located in a same line along the first direction and/or the second direction, are not located in a straight line (see FIGS. 1 to 9). As shown in FIG. 10, the first sub-pixels 11 arranged along the second direction and the second sub-pixels 12 arranged along the second direction are arranged in a wavy line, and it can be achieved that the first pixel row 101 includes the first sub-pixels 11 and at most part of the second sub-pixels 12 or even merely includes the first sub-pixels 11, and the first margin includes merely blue sub-pixels, and the magenta color effect at margins can be weakened, and the human eyes are insensitive to blue, and the color effect at margins is relative weak.

With further reference to FIG. 10, in an embodiment, the second margin includes a second pixel row 102, and the second pixel row 102 includes third sub-pixels 13 and at least part of second sub-pixels 12, but does not include first sub-pixels 11.

As describe above, the first sub-pixels 11 and the second sub-pixels 12 arranged along the second direction may be arranged in a wavy line, and at the second margin facing to the first margin, the second pixel row 102 may include third sub-pixels 13 and at least part of the second sub-pixels 12, or even third sub-pixels 13 and all of the second sub-pixels 12, in which the green color effect at margins at the second margin in the diamond arrangement may be weakened due to the red sub-pixels closing to the second margin.

With further reference to FIG. 10, in an embodiment, the display region AA includes a third margin and a fourth margin opposite to each other along a second direction. The third margin includes a third pixel row 103, and the third pixel row 103 includes first sub-pixels 11, second sub-pixels 12 and part of third sub-pixels 13. The part of the third sub-pixels 13 include odd-th third sub-pixels 13 along the first direction or even-th third sub-pixels 13 along the first direction, and the second direction intersects the first direction.

FIG. 10 illustrates the third margin as a left margin and the fourth margin as a right margin. Referring to the above description, it can be understood that the left margin of diamond arrangement is prone to magenta color effect at a margin and the right margin of diamond arrangement is prone to green effect at a margin. As shown in FIG. 10, in the embodiments of the present disclosure, along the second direction, since third sub-pixels 13 in various lines arranged along the first direction are arranged at intervals in a straight line or in a wavy line, part of the third sub-pixels 13 can be close to the third margin. For example, in FIG. 10, along the first direction, at least part of the odd-th third sub-pixels 13 are close to the third margin, and it is possible to achieve that the third pixel row 103 includes the first sub-pixels 11, the second sub-pixels 12 and part of the third sub-pixels 13. Since the third sub-pixels 13 are close to the third margin, the magenta color effect at margins at the third margin in the diamond arrangement can be weakened. In other embodiments, it is also possible that at least part of the even-th third sub-pixels 13 are close to the third margin, which will not be described herein.

With further reference to FIG. 10, in an embodiment, the fourth margin includes a fourth pixel row 104, and the fourth pixel row 104 includes odd-th third sub-pixels 13 arranged along the first direction or even-th third sub-pixels 13 arranged along the first direction. The fourth pixel row 104 does not include the first sub-pixels 11 and the second sub-pixels 12.

Similarly, in the embodiments of the present disclosure, along the second direction, since third sub-pixels 13 in various lines arranged along the first direction are arranged at intervals in a straight line or in a wavy line, part of the third sub-pixels 13 can be farther away from the fourth margin. For example, at least part of the odd-th third sub-pixels 13 arranged along the first direction can be farther away from the fourth margin, or at least part of the even-th third sub-pixels 13 arranged along the first direction can also be farther away from the fourth margin, and the green sub-pixels at the fourth margin can be reduced, therefore, the green color effect at margins at the fourth margin in the diamond arrangement can be weakened.

It should be understood that the above-mentioned FIG. 10 with respect to the first sub-pixels/second sub-pixels/third sub-pixels included in the first pixel row, the second pixel row, the third pixel row and the fourth pixel row merely refers to a line of first sub-pixels/second sub-pixels/third sub-pixels close to a most corresponding margin.

Based on the scheme shown in FIG. 7 in which centers of two first sub-pixels 1111 and centers of two second sub-pixels 1212 adjacent to a same third sub-pixel 13 constitute an isosceles trapezoid 6, the display panel will be further described.

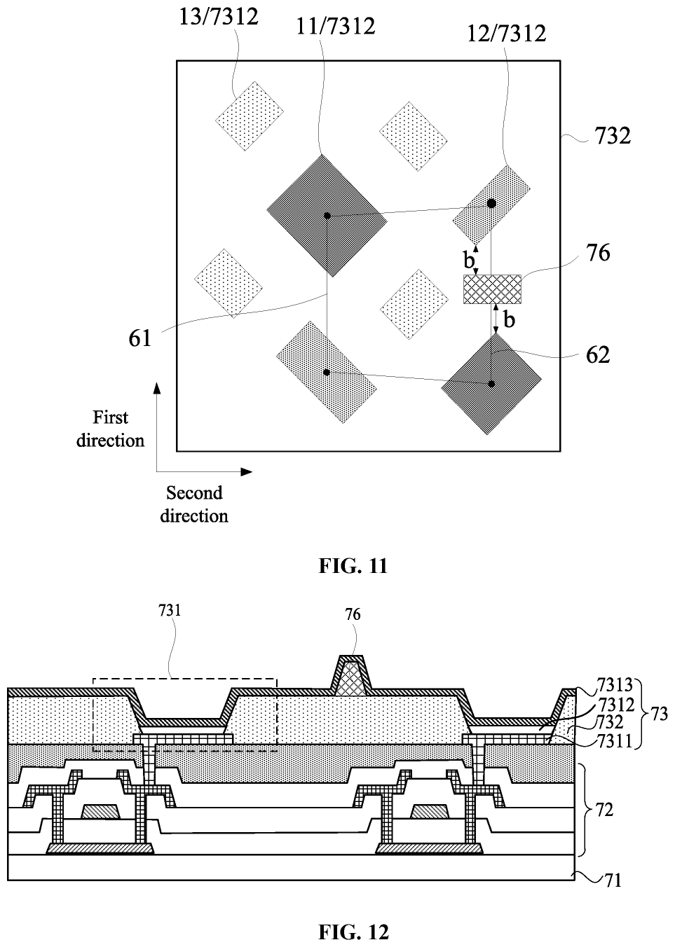

FIG. 11 is a partial structural diagram of a display panel according to an embodiment of the present disclosure, and FIG. 12 is a sectional view of the display panel shown in FIG. 11. Referring to FIGS. 11 and 12, in an embodiment, the display panel includes a substrate 71 and a support column 76, and in a direction perpendicular to a plane where the substrate 71 is located, the support column 76 overlaps a longer one of the first edge 61 and the second edge 62.

Referring to FIG. 12, the display panel may further include pixel circuit layers 72 and a display layer 73 located on a side of the pixel circuit layers 72 facing away from the substrate 71. The display layer 73 includes a pixel definition layer 732 and light-emitting elements 731. The display panel may further include a support column 76 located on a side of the pixel definition layer 732 facing away from the substrate 71. The pixel definition layer 732 includes pixel openings, and each of the pixel openings may correspond to a respective one of the light-emitting elements 731. In conjunction with FIG. 11, in the direction perpendicular to the plane where the substrate 71 is located, the support column 76 overlaps a longer one of the first edge 61 and the second edge 62.

Each pixel circuit layer 72 may include pixel circuits for driving the light-emitting elements to emit light. FIG. 12 merely shows the structure of part of transistors in each pixel circuit layer 72. The structure of the pixel circuits will not be explained further herein. Design of the required pixel circuits may be according to the requirements. The light-emitting elements in each of the first sub-pixel 11, the second sub-pixel 12 and the third sub-pixel 13 have different light-emitting colors. For example, the first sub-pixel 11 includes a first light-emitting element emitting blue light, the second sub-pixel 12 includes a second light-emitting element emitting red light, and the third sub-pixel 13 includes a third light-emitting element emitting green light. As shown in FIG. 12, a light-emitting element 731 may include an anode 7311, a light-emitting layer 7312 and a cathode 7313, and each of the pixel openings in the pixel definition layer 732 corresponds to a respective one of the light-emitting elements 731.

In a preparation process, referring to FIG. 12, after a pixel opening is formed on the pixel definition layer 732 to expose the anode 7311, a corresponding luminescent material is evaporated in the pixel opening using a mask to form the light-emitting layer 7312. In an embodiment, the light-emitting layers 7312 of the light-emitting elements with different light-emitting colors may be evaporated using different masks. In order to avoid direct contact between the mask and the pixel definition layer 732, it is necessary to provide a support column 76 above the pixel definition layer 732 to support the mask.

As shown in FIG. 11, since in the isosceles trapezoid constituted by two first sub-pixels 11 adjacent to a same third sub-pixel 13 and two second sub-pixels 12 adjacent to a same third sub-pixel 13, the first margin 61 and the second margin 62 have length differences. In the embodiments of the present disclosure, the support column 76 may be made to have a larger setting space, by setting the support column 76 overlapping the longer one of the first edge 61 and the second edge 62, i.e., setting the support column 76 above the pixel definition layer 732 between a first sub-pixel opening and a second sub-pixel opening with a larger distance. In addition, for the support columns 76 having a same size, according to the solutions provided in the present disclosure, a larger distance from the support column 76 to the first sub-pixel opening and a larger distance from the support column 76 to the second sub-pixel opening are provided, to avoid the support column 76 from blocking the light emitted by the light-emitting elements 731 and reducing the color drift. As an example, the length of the second edge 62 of the isosceles trapezoid in FIG. 11 is larger than the length of the first edge 61 of the isosceles trapezoid in FIG. 11, therefore, the support column 76 is provided to overlap the second edge 62.

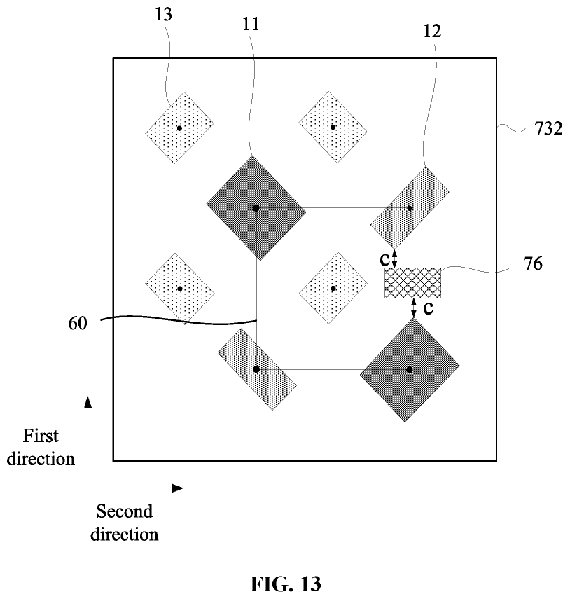

As an example, FIG. 13 is a partial structural diagram of a display panel in the related art, in which the diamond arrangement is taken as an example. As shown in FIG. 13, two first sub-pixels 11 adjacent to a same third sub-pixel 13 and two second sub-pixels 12 adjacent to a same third sub-pixel 13 constitute a rectangle. For the convenience of displaying the contrast effect, a left side edge 60 of the rectangle in FIG. 13 is equal in length to the first edge 61 of the isosceles trapezoid in FIG. 11, the first sub-pixel 11 and the second sub-pixel 12 in FIG. 13 are identical to the first sub-pixel 11 and the second sub-pixel 12 with smaller sizes in FIG. 11, and the length of the support column 76 in FIG. 11 along the first direction and the length of the support column 76 in FIG. 13 along the first direction are equal. As can be seen by comparing FIG. 11 and FIG. 13, a distance b between the support column 76 and the first pixel opening and the second pixel opening in FIG. 11 is greater than a distance c between the support column 76 and the first pixel opening and the second pixel opening in FIG. 13, which shows that in the embodiments of the present disclosure, the setting space of the support column 76 can be enlarged by setting two first sub-pixels 11 adjacent to a same third sub-pixel 13 and two second sub-pixels 12 adjacent to a same third sub-pixel 13 to constitute the isosceles trapezoid and setting the support column 76 disposed at a position where a long edge (such as the second edge 62) of the isosceles trapezoid is located. In addition, for the support columns 76 having a same size, the distance between the support column 76 and the first sub-pixel opening can be enlarged, and the distance between the support column 76 and the second sub-pixel opening can be enlarged, the support column 76 can be prevented from blocking the light emitted by the light-emitting elements 731, and the color drift can be reduced.

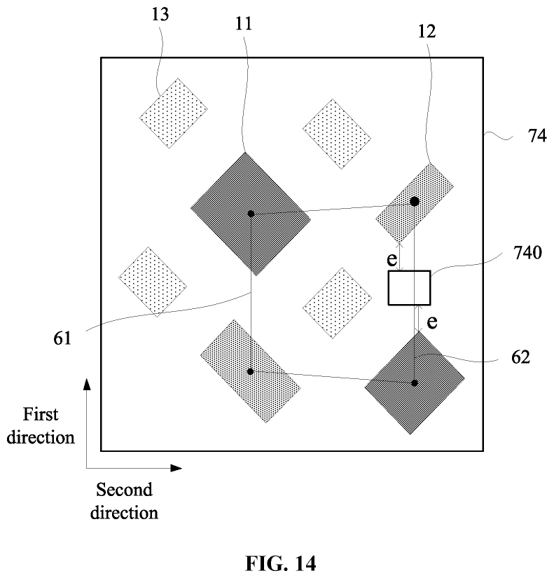

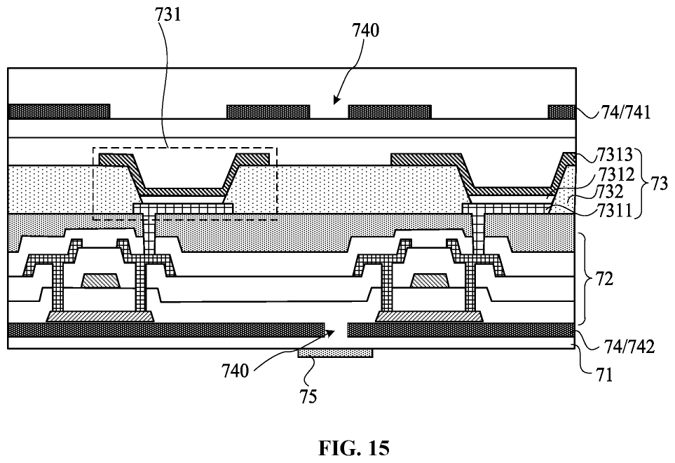

FIG. 14 is another partial structural diagram of a display panel according to an embodiment of the present disclosure, and FIG. 15 is a sectional view of the display panel shown in FIG. 14. Referring to FIGS. 14 and 15, in an embodiment, the display panel may further include a substrate 71, a light-shielding layer 74 and a light-sensing sensor 75. The light-shielding layer 74 includes light-transmitting apertures 740, and in a direction perpendicular to a plane where the substrate 71 is located, the light-sensing sensor 75 overlaps a respective one of the light-transmitting apertures 740. In an embodiment, in the direction perpendicular to the plane where the substrate 71 is located, each of the light-transmitting apertures 740 overlaps a longer one of the first edge 61 and the second edge 62.

The light-sensing sensor 75 may be used, for example, for implementing fingerprint identification. The light-shielding layer 74 is provided with light-transmitting apertures 740, and part of light-emitting elements 731 in the display layer 73 also serves as fingerprint identification light sources. After light generated by the light-emitting elements 731 reaches a fingerprint and a contact surface of the display screen, since fingerprint valleys and fingerprint ridges have different reflection degrees for the light, the reflected back light is incident to the light-sensing sensor 75 through the light-transmitting apertures 740. A fingerprint image may be imaged to the light-sensing sensor 75 through the aperture imaging principle to achieve the fingerprint identification.

As shown in FIG. 14, since in the isosceles trapezoid constituted by two first sub-pixels 11 adjacent to a same third sub-pixel 13 and two second sub-pixels 12 adjacent to a same third sub-pixel 13, the first edge 61 and the second edge 62 have length differences, in the embodiments of the present disclosure, the light-transmitting apertures 740 can be made to have more space to set the light-transmitting apertures 740 by setting the light-transmitting apertures 740 overlapping the longer one of the first edge 61 and the second edge 62, and then an aperture diameter of the light-transmitting apertures 740 along a extending direction (the first direction) of the first edge 61/the second edge 62 can be enlarged, and a light-transmitting area of the light-transmitting apertures 740 can be enlarged, a quantity of fingerprint identification signals can be increased, the fingerprint identification time can be shortened, and the adverse effect caused by diffraction of the light-transmitting apertures 740 can be reduced. As an example, the length of the second edge 62 of the isosceles trapezoid in FIG. 14 is larger than the length of the first edge 61 of the isosceles trapezoid in FIG. 14, therefore, the light-transmitting apertures 740 are provided to overlap the second edge 62.

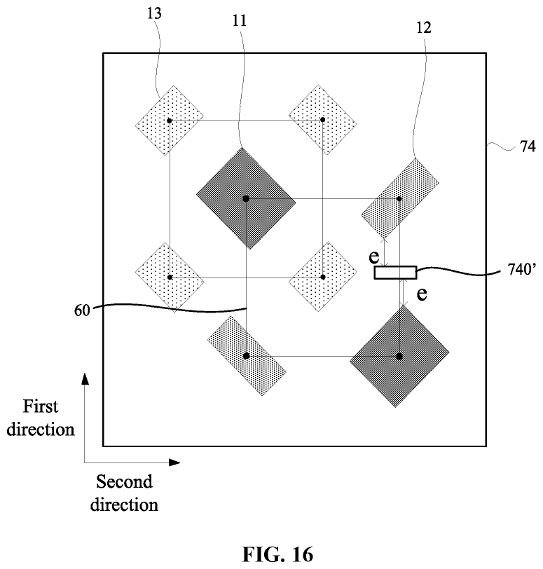

As an example, FIG. 16 is another partial structural diagram of a display panel in the related art. Taking the diamond arrangement as an example, as shown in FIG. 16, two first sub-pixels 11 adjacent to a same third sub-pixel 13 and two second sub-pixels 12 adjacent to a same third sub-pixel 13 constitute a rectangle. For the convenience of displaying the contrast effect, a left side edge 60 of the rectangle in FIG. 16 is equal in length to the first edge 61 of the isosceles trapezoid in FIG. 14, the first sub-pixel 11, and the second sub-pixel 12 in FIG. 16 are identical to the first sub-pixel 11 and the second sub-pixel 12 with smaller size in FIG. 14, and along the first direction, a distance e between a light-transmitting aperture (740/740′) and the first sub-pixel 11 in FIG. 14 is equal to a distance e between a light-transmitting aperture (740/740′) and the second sub-pixel 12 in FIG. 16. As can be seen by comparing FIG. 14 and FIG. 16, along the first direction, an aperture diameter of the light-transmitting apertures 740 in FIG. 14 is greater than an aperture diameter of the light-transmitting apertures 740′ in FIG. 16, which shows that in the embodiments of the present disclosure, the aperture diameter of the light-transmitting apertures 740 along the first direction can be enlarged by setting two first sub-pixels 11 adjacent to a same third sub-pixel 13 and two second sub-pixels 12 adjacent to a same third sub-pixel 13 to constitute the isosceles trapezoid and setting the light-transmitting apertures 740 disposed at a position where a long edge (such as the second edge 62) of the isosceles trapezoid is located, and then the light-transmitting area of the light-transmitting apertures 740 can be enlarged, the quantity of fingerprint identification signals can be increased, the fingerprint identification time can be shortened, and the adverse effect caused by diffraction of the light-transmitting apertures 740 can be reduced.

It should be noted that the embodiment of the present disclosure is not limited to the number of the light-shielding layers 74. FIG. 15 illustrates that the light-shielding layer 74 includes a first light-shielding layer 741 and a second light-shielding layer 742. In other embodiments, the display panel may include merely one light-shielding layer 74. Other structures in the display panel may be described with reference to the above embodiments, and will not be described herein.

Referring to FIG. 7, both the first edge 61 of the isosceles trapezoid and the second edge 62 of the isosceles trapezoid are parallel to the first direction. In this case, considering the process yield, the first direction is a column direction, and the second direction is a row direction.

In the evaporation process of, for example, the light-emitting layer, the first direction is provided with an angle plate, and the second direction is not provided with the angle plate. In a case where the first direction is provided with the angle plate, when the light-emitting layer 7312 of each sub-pixel arranged in the first direction is evaporated, the evaporation accuracy is relative high, and it is possible to prevent the luminescent material of the light-emitting layer of the first sub-pixel 11 from falling into the pixel opening corresponding to the second sub-pixel 12 adjacent to the first sub-pixel 11 or prevent the luminescent material of the light-emitting layer of the second sub-pixel 12 from falling into the pixel opening corresponding to the first sub-pixel 11 adjacent to the second sub-pixel 12. In a case where the second direction is not provided with the angle plate, the evaporation accuracy is relative low, in this case, if a distance between the first sub-pixel 11 and the second sub-pixel 12 adjacent to each other in the second direction is short, the luminescent material of the light-emitting layer of the first sub-pixel 11 may fall into the pixel opening corresponding to the adjacent second sub-pixel 12, and the luminescent material of the light-emitting layer of the second sub-pixel 12 may fall into the pixel opening corresponding to the adjacent first sub-pixel 11, thus resulting color drift.

Therefore, in the embodiments of the present disclosure, in a direction (the second direction) where the angle plate is not provided, the distance between the first sub-pixel 11 and the second sub-pixel 12 is increased, that is, in the second direction, compared with an existing arrangement in which two first sub-pixels 11 adjacent to a same third sub-pixel 13 and two second sub-pixels 12 adjacent to a same third sub-pixel 13 constitute a rectangle (for example, a diamond arrangement), the distance between the first sub-pixel 11 and the second sub-pixel 12 in the second direction may be increased by setting the center of the first sub-pixel 11 and the center of the second sub-pixel 12 respectively located at two endpoints of a hypotenuse of the isosceles trapezoid 6. In this way, even if the second direction is not provided with the angle plate, the evaporation accuracy can also be improved to prevent the luminescent material of the light-emitting layer of the first sub-pixel 11 from falling into the pixel opening corresponding to the adjacent second sub-pixel 12, or prevent the luminescent material of the light-emitting layer of the second sub-pixel 12 from falling into the pixel opening corresponding to the adjacent first sub-pixel 11, to reduce the risk of color drift, increasing the process margin and improving the yield.

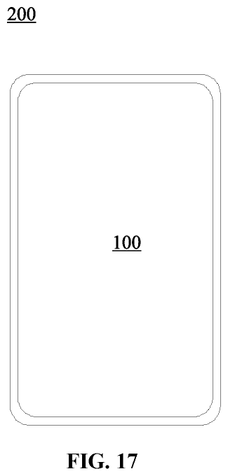

Based on the same concept, the embodiment of the present disclosure further provides a display device. FIG. 17 is a structural diagram of a display device according to an embodiment of the present disclosure. The display device 200 includes the display panel 100 of any of the above embodiments, to have the same beneficial effects as the above display panel; similarities may be understood with reference to the above description of the display panel and will not be described herein. The display device 200 provided by the embodiments of the present disclosure may be the phone shown in FIG. 17, or may be any electronic product with display function, including but not limited to the following categories: television, laptop, desktop display, tablet computer, digital camera, smart bracelet, smart glasses, vehicle-mounted display, medical equipment, industrial control equipment, touch interactive terminal, etc., and no limitations are made thereto in the embodiments of the present disclosure.

What is claimed is:

1. A display panel, comprising:
a plurality of pixel repetitive units arranged in an array, wherein each pixel repetitive unit of the plurality of pixel repetitive units comprises two first sub-pixels, two second sub-pixels and four third sub-pixels;
wherein in the display panel:
a first sub-pixel of the two first sub-pixels is located among the four third sub-pixels, a second sub-pixel of the two second sub-pixels is located among the four third sub-pixels, and one third sub-pixel is simultaneously located between the two first sub-pixels and between the two second sub-pixels; and
centers of the four third sub-pixels surrounding the first sub-pixel constitute a first irregular quadrangle, wherein lengths of each pair of opposite edges of the first irregular quadrangle are not equal.

2. The display panel of claim 1, wherein light emitting areas of the four third sub-pixels are equal to each other.

3. The display panel of claim 1, wherein centers of the four third sub-pixels surrounding the second sub-pixel constitute a second irregular quadrangle, wherein lengths of each pair of opposite edges of the second irregular quadrangle are not equal.

4. The display panel of claim 1, wherein among third sub-pixels arranged along a first direction, centers of third sub-pixels in an odd-th line are located in a first wavy line, and centers of third sub-pixels in an even-th line are located in a first straight line; or centers of third sub-pixels in an odd-th line are located in a first straight line, and centers of third sub-pixels in an even-th line are located in a first wavy line; and wherein the first direction is a row direction or a column direction.

5. The display panel of claim 4, wherein a distance Di is provided between a line connecting highest points in the first wavy line and a line connecting lowest points in the first wavy line, and 0<D1≤L₁/8; and wherein Li is a length of a pixel setting region along a second direction, the second direction intersects the first direction, and the pixel setting region covers an entire region of a first sub-pixel and a partial region of four third sub-pixels surrounding the first sub-pixel, or the pixel setting region covers an entire region of a second sub-pixel and a partial region of four third sub-pixels surrounding the second sub-pixel.

6. The display panel of claim 4, wherein among third sub-pixels arranged along a second direction, centers of third sub-pixels in an odd-th line are located in a second wavy line, and centers of third sub-pixels in an even-th line are located in a second straight line; or centers of third sub-pixels in an odd-th line are located in a second straight line, and centers of third sub-pixels in an even-th line are located in a second wavy line; wherein the second direction intersects the first direction.

7. The display panel of claim 6, wherein light emitting areas of two first sub-pixels adjacent to a same third sub-pixel are different; or wherein light emitting areas of two second sub-pixels adjacent to a same third sub-pixel are different.

8. The display panel of claim 4, wherein centers of third sub-pixels arranged along a second direction are located in third wavy lines, and the second direction intersects the first direction.

9. The display panel of claim 8, wherein in each third wavy line, a distance between a line connecting highest points of a third wavy line and a line connecting lowest points of the third wavy line is equal; and
wherein centers of four adjacent third sub-pixels constitute an irregular trapezoid; and centers of the two first sub-pixels and centers of the two second sub-pixels adjacent to a same third sub-pixel constitute an isosceles trapezoid.

10. The display panel of claim 9, wherein the isosceles trapezoid comprises a first edge parallel to the first direction and a second edge parallel to the first direction; and
a length a of the first edge and a length b of the second edge satisfy 0<|a-b|>L₂/4; L₂ is a length of a pixel setting region along the first direction; and
the pixel setting region covers an entire region of a first sub-pixel and a partial region of four third sub-pixels surrounding the first sub-pixel, or the pixel setting region covers an entire region of a second sub-pixel and a partial region of four third sub-pixels surrounding the second sub-pixel.

11. The display panel of claim 10, further comprising:
a substrate; and
a support column, wherein in a direction perpendicular to a plane where the substrate is located,
the support column overlaps a longer one of the first edge of the isosceles trapezoid and the second edge of the isosceles trapezoid.

12. The display panel of claim 10, further comprising:
a substrate; and
a light-shielding layer, where the light-shielding layer comprises a plurality of light-transmitting apertures;
wherein in a direction perpendicular to a plane where the substrate is located, each light-transmitting aperture overlaps a longer one of the first edge of the isosceles trapezoid and the second edge of the isosceles trapezoid.

13. The display panel of claim 4, wherein centers of third sub-pixels arranged along a second direction are located in third straight lines, and the second direction intersects the first direction; and
wherein light emitting areas of two first sub-pixels adjacent to a same third sub-pixel are different; and light emitting areas of two second sub-pixels adjacent to a same third sub-pixel are different.

14. The display panel of claim 1, wherein a distance between a first sub-pixel and each of four most adjacent first sub-pixels is equal.

15. The display panel of claim 1, wherein a distance between a second sub-pixel and four most adjacent second sub-pixels is equal.

16. The display panel of claim 1, wherein centers of four second sub-pixels most adjacent to a same first sub-pixel constitute a first rectangle, a first diagonal of the first rectangle is parallel to a first direction, a second diagonal of the first rectangle is parallel to a second direction, and the first direction intersects the second direction.

17. The display panel of claim 1, wherein centers of four first sub-pixels most adjacent to a same second sub-pixel constitute a second rectangle, a first diagonal of the second rectangle is parallel to a first direction, a second diagonal of the second rectangle is parallel to a second direction, and the first direction intersects the second direction.

18. The display panel of claim 1, wherein a shape of each of the two first sub-pixels, a shape of each of the two second sub-pixels and a shape of each of the four third sub-pixels each is a rectangular, and an aspect ratio L/W of the rectangle satisfies 1<L/W≤1.5.

19. The display panel of claim 1, wherein a virtual edge of a third sub-pixel is in contact with a virtual edge of each of two adjacent first sub-pixels, and a virtual edge of the third sub-pixel is in contact with a virtual edge of each of two adjacent second sub-pixels.

20. The display panel of claim 4, further comprising a display region, wherein the display region comprises a first margin and a second margin opposite to each other along the first direction; and
wherein the first margin comprises a first pixel row, and the first pixel row comprises first sub-pixels and at most part of second sub-pixels, and does not comprise a third sub-pixel.

21. The display panel of claim 4, further comprising a display region, wherein the display region comprises a first margin and a second margin opposite to each other along the first direction; and
wherein the second margin comprises a second pixel row, and the second pixel row comprises third sub-pixels and at least part of second sub-pixels, and does not comprise a first sub-pixel.

22. The display panel of claim 4, further comprising a display region, wherein the display region comprises a third margin and a fourth margin opposite to each other along a second direction;
the third margin comprises a third pixel row, and the third pixel row comprises first sub-pixels, second sub-pixels and part of third sub-pixels;
the part of the third sub-pixels comprises odd-th third sub-pixels arranged along the first direction or even-th third sub-pixels arranged along the first direction; and
the second direction intersects the first direction.

23. The display panel of claim 4, further comprising a display region, wherein the display region comprises a third margin and a fourth margin opposite to each other along a second direction;
the fourth margin comprises a fourth pixel row, and the fourth pixel row comprises odd-th third sub-pixels arranged along the first direction or even-th third sub-pixels arranged along the first direction; and
the second direction intersects the first direction.

24. A display device, comprising a display panel, wherein the display panel comprises:
a plurality of pixel repetitive units arranged in an array, wherein each pixel repetitive unit of the plurality of pixel repetitive units comprises two first sub-pixels, two second sub-pixels and four third sub-pixels;
wherein in the display panel:
a first sub-pixel of the two first sub-pixels is located among the four third sub-pixels, a second sub-pixel of the two second sub-pixels is located among the four third sub-pixels, and one third sub-pixel is simultaneously located between the two first sub-pixels and between the two second sub-pixels; and
centers of the four third sub-pixels surrounding the first sub-pixel constitute a first irregular quadrangle, wherein lengths of each pair of opposite edges of the first irregular quadrangle are not equal.
